(19) United States
(12) Patent Application Publication
(10) Pub. No.: US 2014/0321062 A1
(43) Pub. Date: Oct. 30, 2014

(54) HEAT SINK

(71) Applicant: HEWLETT-PACKARD DEVELOPMENT COMPANY, L.P., Houston, TX (US)

(72) Inventors: Kah Hoe Ng, Gelang Patah (MY); Tzye Perng Poh, Singapore (SG); Kay Seah Ng, Singapore (SG)

(73) Assignee: Hewlett-Packard Development Company, L.P., Houston, TX (US)

(21) Appl. No.: 13/870,650

(22) Filed: Apr. 25, 2013

(51) Int. Cl. H05K 1/02

(52) U.S. Cl. CPC H05K 1/0204
USPC 361/719; 165/185

(57) ABSTRACT

A heat sink that is suitable for mounting on a printed circuit board (PCB) and dissipating heat from an integrated chip (IC).

### BACKGROUND

Integrated chips (ICs) are often mounted on a printed circuit board (PCB) and draw power and receive data or control signals through conductive lines of the printed circuit board. One way of mounting an IC to a PCB is to use a ball grid array (BGA), which is a grid of solder ball connections. In some cases a heat sink is positioned on top of the IC in order to help dissipate heat.

### BRIEF DESCRIPTION OF THE DRAWINGS

Examples will now be described, by way of non-limiting example only, with reference to the accompanying drawings, in which:

FIG. 1 is a schematic view of a device according to one example of the present disclosure;

FIG. 2A is a schematic view of a device according to one example of the present disclosure;

FIG. 2B is a perspective view of a device according to one example of the present disclosure;

FIG. 2C is a perspective view of a device according to one example of the present disclosure;

FIG. 3 is a schematic view of a device according to one example of the present disclosure;

FIG. 4 is a top down view of the example shown in FIG. 3;

FIG. 5 is another top down view of the example shown in FIG. 3; and

FIG. 6 is another top down view of the example shown in FIG. 3 showing a different configuration to FIG. 5.

### DETAILED DESCRIPTION

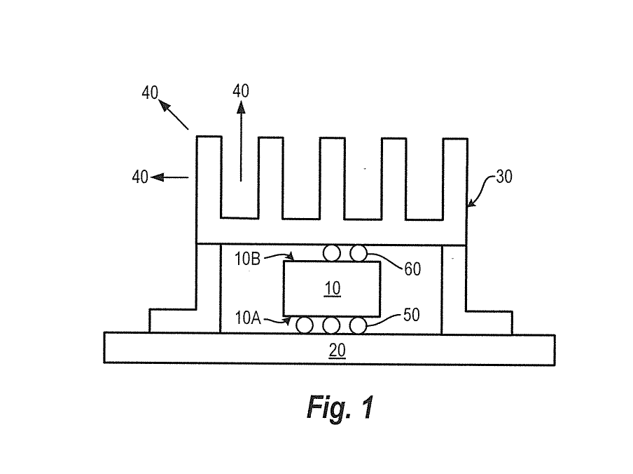

FIG. 1 is a general schematic view showing an example of a device including an integrated chip (IC) 10 mounted on a printed circuit board (PCB) 20. The IC 10 has a first side 10A which is electrically connected to the PCB 20 by a first electrically conductive connection 50 and a second side 10B which is electrically connected to the heat sink 30 by a second electrically conductive connection 60. The first and second electrically conductive connections 50, 60 may be any suitable connection such as quad flat package (QFP), lead frame, dual inline connecting structure etc. In one example, one or both of the first and second electrically conductive connections are high density connections such as ball grid arrays (BGA), or pin grid arrays. The heat sink 30 is in thermal contact with the IC and acts to dissipate heat from the IC 10 in a direction 40 away from the IC 10 and PCB 20.

As the heat sink 30 is electrically connected to the IC 10, electrical power may delivered to the IC via the heat sink. This may free up one or more connections 50 of the PCB to the IC, which would otherwise be used to deliver electrical power. This may be helpful, as modern ICs can require a high density of connections.

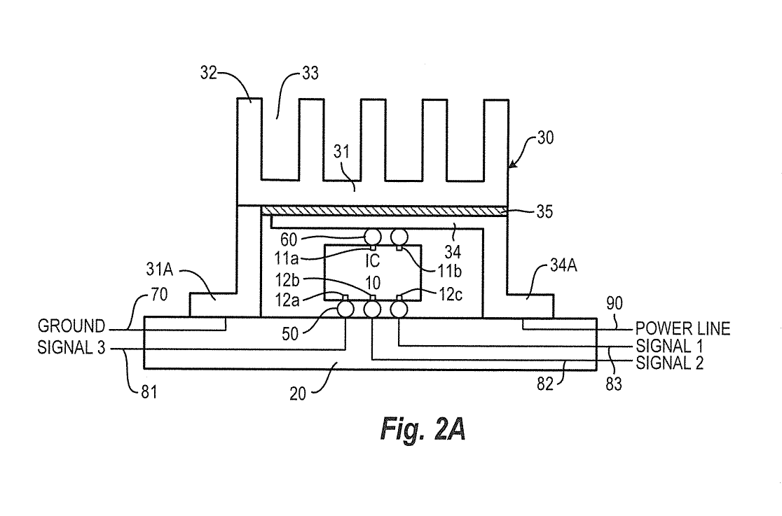

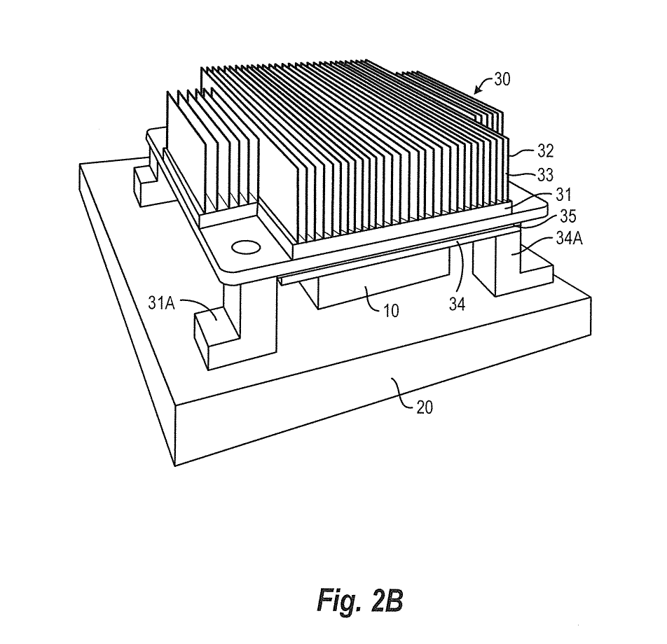

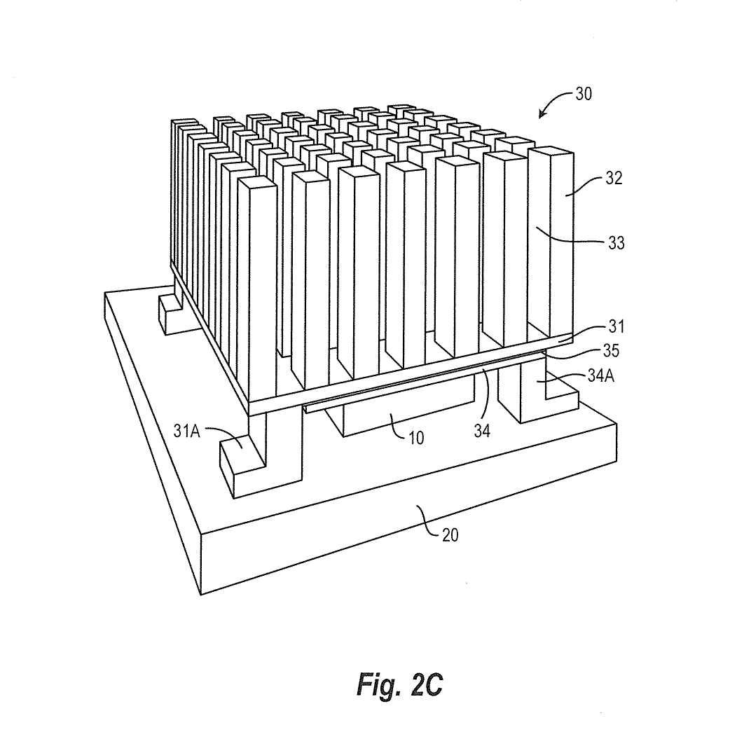

FIG. 2A shows another example in more detail. In FIG. 2A the IC 10 is connected to the PCB 20 by a first ball grid array (BGA) 50 and connected to the heat sink 30 by a second BGA 60. More specifically the heat sink 30 includes a first electrically conductive layer 31 and a second electrically conductive layer 34, which are electrically insulated from each other by an electrically insulating material 35. The electrically insulating material 35 may be thermally conductive so as not to disrupt passage of heat from the IC through the heat sink. In one example the material 35 is a silicone thermal pad, in another example the material 35 may be a thermally conductive but electrically insulating glue, or paste, or ‘thermal grease’ (which is a thermally conductive viscous fluid substance comprising ceramic and/or silicone).

As shown in FIG. 2A, the first electrically conductive layer 31 of the heat sink is electrically connected (i.e. has an electrically conductive connection) to a ground plane 70 by a leg 31A. This connection to ground enables the heat sink 30 to act as an electromagnetic interference (EMI) shield for the IC. As the heat sink partially or wholly covers one face of the IC, EMI coming from that direction may be absorbed by the heat sink and conducted to ground.

The second electrically conductive layer 34 of the heat sink connects to a power line 90 via a leg 34A and is connected to one or more power inputs 11a, 11b of the IC via the second BGA 60. As the first electrically conductive layer 31 and second electrically conductive layer 34 are electrically insulated from each other, the heat sink may act both as an EMI shield connected to the ground plane, and as a path for routing electrical power to the IC.

The first BGA 50 connects a plurality of signal lines 81, 82, 83 of the PCB to the signal inputs 12a, 12b, 12c of the IC. A signal input is an input for receiving a control or data signal, in contrast to power input which is for receiving electrical power to drive the IC (typically at a specified voltage or voltage range). Whilst only three separate signal lines 81, 82 and 83 are shown in FIG. 2A, in practice there may be hundreds or thousands of BGA connections and signal lines. As ICs get more sophisticated they may need more signal inputs as well as power inputs, but as technology progresses and ICs get faster, the IC often gets smaller as well. This can lead to a very high density of connections between the PCB and the IC. Space is at a premium. By providing some power inputs at the upper side of the IC, more room is made on the opposite (bottom) side of the IC for additional signal inputs.

The heat sink includes a base 31 and a plurality of projections 32 projecting from the base. The base and projections may be one piece or separate pieces and may be made of metal due to the thermally conductive properties of metal. The base itself may form the first electrically conductive layer (as in FIG. 2A), or the first electrically conductive layer may have an electrically conductive connection to the base. Heat is typically conducted from the IC to the base 31 and from the base 31 to the projections 32. The projections 32 (also referred to as ‘projecting portions’ or ‘heat dissipating members’) are spaced apart from each other and surrounded by air. Thus heat may radiate from the projecting portions into the surrounding air and away from the heat sink. Due to the projecting portions, the heat sink has a large surface area and so heat may be dissipated relatively efficiently.

FIGS. 2B and 2C are perspective drawings showing the heat sink and PCB as seen from above. The projecting portions 32 may take any convenient form. In one example they may be ribs or fins as shown in FIG. 2B. In another example they may be an array of elongate fingers as shown in FIG. 2C. In both cases, the spaces 33 between the projections 32 allow heat to be efficiently dissipated from the projections 32 to the surrounding air.

The base 31 may have legs 31A for supporting the heat sink over the IC and the legs 31A may be secured to the PCB (e.g. by a screw, other mechanical attachment or solder). The base 31 may form part of the first electrically conductive layer. The legs 31A form part of or are in electrically conductive contact with the first conductive layer of the heat sink. The legs 31A form an electrically conductive path between the base 31 and a ground plane of the PCB. The electromagnetic interference picked up by the base 31 and can be safely conducted to ground. A leg 34A electrically connects the second electrically conductive layer 34 to a power line. Note that the second electrically conductive layer 34 does not contact with the legs 31A (there is an air gap as shown in FIG. 2A or an electrically insulating material between the layer 34 and leg 31A).

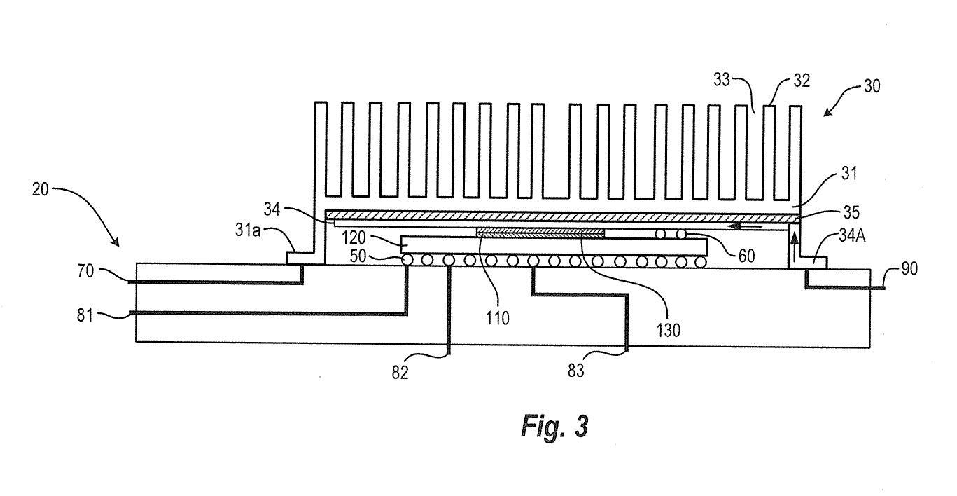

FIG. 3 is a more detailed example of a device including an IC between a heat sink 30 and a PCB 20. The parts which are different from FIG. 2A will now be described. The IC includes an IC die 110 and an IC substrate 120. The IC die 110 is the ‘intelligent’ part which carries out processing and may comprise a set of electronic circuits on a small plate of semiconductor material. The IC substrate 120 comprises ‘internal’ signal and power lines (not shown) embedded in an electrically insulating material. The internal signal and power lines of the substrate 120 connect electrical contact pads or vias of the substrate 120 to signal and power inputs of the IC die 110. Due to the small size of the diagram these internal lines, inputs, contact pads and other internal structure of the IC die 110 and IC substrate 120 are not shown in FIG. 3. BGAs or other connections 50, 60 are used to connect the contact pads or vias of the IC substrate 120 to external signal lines 81, 82, 83 and one or more external power lines 90 (‘external’ meaning external to the IC die and substrate). E.g. The BGAs 50, 60 may for example connect the IC to conductive lines 81, 82, 83 of the PCB 20 or to the second conductive layer 34 of the heat sink).

An electrically insulating, but thermally conductive layer 130 (e.g. a thermal pad, thermal grease etc) is provided between the upper surface of the IC die 110 and the lower surface of the heat sink 30. This allows the heat sink to conduct heat away from the IC while shielding the upper surface of the IC from unwanted electrical currents. The first BGA 50 provides a plurality of connections between the first (lower) side of the IC substrate 120 and the PCB 20. The ball connections of the BGA may electrically connect vias or contact pads on the underside of the IC substrate 120 with a via or contact pad of the PCB 20. The vias or contact pads of the PCB lead to conductive lines 81, 82, 83 running through one or more layers of the PCB so that data and control signals may be sent to or received from the IC. It is also possible to route power lines to the underside of the IC substrate 120, but in the illustrated example all the power lines are routed to the upper side of the IC substrate 120 via the second BGA 60 and second conductive layer 34 of the heat sink, so that more connections are available for signal lines at the bottom of the IC substrate 120. While only three signal lines 81, 82 and 83 are shown in FIG. 3, in practice there may be hundreds or thousands of lines and connections to the IC.

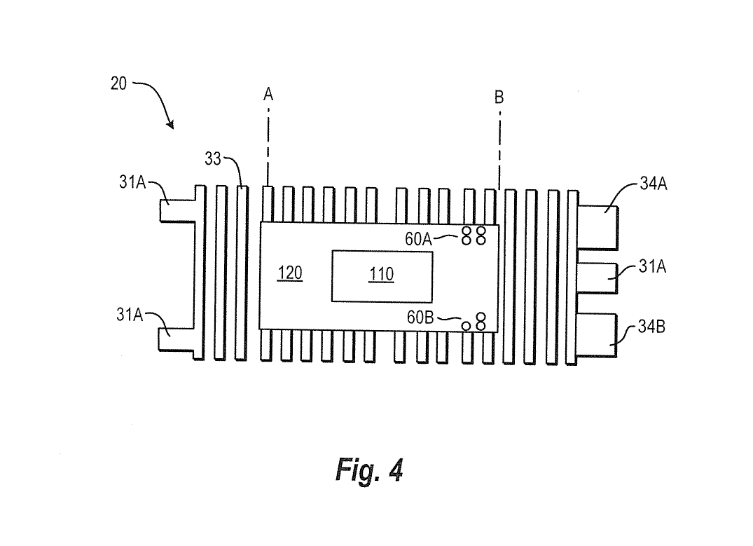

FIG. 4 is a view of FIG. 3 from above. So that the position of the IC can be easily seen, the heat sink 30 including layer 35 and the electrically insulating layer 130 have been stripped out of FIG. 4 in the region between the dotted lines A and B. First leg portions 31A of the heat sink connect the first conductive layer 31 of the heat sink to a ground plane 70 of the PCB.

Meanwhile a first set connections 60A and second set of connections 60B of the second BGA 60 are shown on the upper surface of the IC substrate 120. These connections 60A, 60B connect the second electrically conductive layer 34 of the heat sink to conductive lines of the IC substrate 120 which lead to power inputs of the IC die 110. Second leg portions 34A of the heat sink connect a power line 90 of the PCB which leads to an external power module or power source. The BGA connections 60A, 60B and the second leg portions 34A, 34B are connected to each other by the second electrically conductive layer 34 of the heat sink as shown FIG. 3 and FIGS. 5 and 6 below.

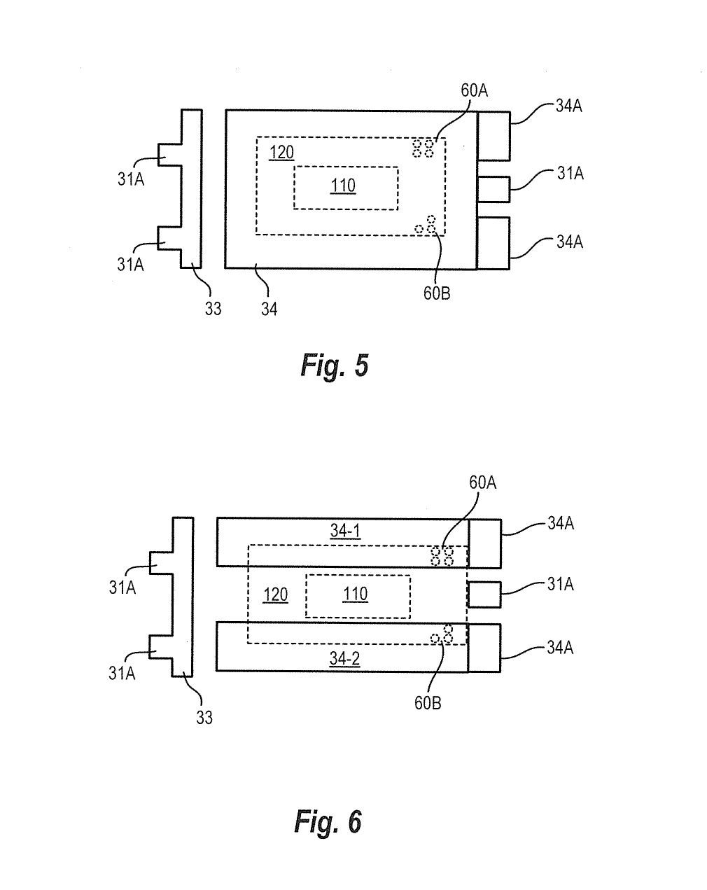

FIG. 5 is another view from above, similar to FIG. 4, but also shows the second conductive layer 34. As the second conductive layer 34 covers the IC die 110, IC substrate 120 and BGA connections 60A, 60B, the position of the IC die 110, IC substrate 120 and BGA connections 60A, 60B are shown by dotted lines in FIG. 4. The second electrically conductive layer 34 and the second leg portions 34A and 34B may be formed of the same piece or may be separate pieces. In FIG. 5, the second electrically conductive layer 34 is a rectangular planar sheet, but this just an example and it could have other shapes. The second electrically conductive layer 34 is not in electrical contact with the first leg portions 31A which lead to ground; they may be insulated from each other by an insulating layer 35, or by a sufficient air gap.

FIG. 6 is another example in which the second conductive layer includes two separate conductive rails or power lines 34-1 and 34-2. The first power line 34-1 connects the first set of BGA balls 60A with one of the second leg portions 34A. The second power line 34-2 connects the second set of BGA balls 60B with the other second leg portion 34B. The first and second power rails 34-1, 34-2 are electrically insulated from each other. For example they may be set in an electrically insulating material or laid as conductive lines adhered to the electrically insulating layer 35 above etc. As the power rails (or ‘power lines’) are electrically insulated from each other they may be used to carry different voltages to the IC. This may be useful if the IC is of a type which requires more than one different voltage input. Typically the IC specification will state the voltage or voltage range for each power input. The second electrically conductive layer power rails 34-1 and 34-2 are not in electrical contact with the first leg portions 31A which lead to ground; they may be insulated from each other by an insulating layer 35, or by a sufficient air gap.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A device comprising:
a printed circuit board (PCB), a heat sink and an integrated chip (IC), the IC having a first side which is connected to the PCB by a first electrically conductive connection and a second side which is connected to the heat sink by a second electrically conductive connection; the first side being opposite the second side.

2. The device of claim 1 wherein the heat sink includes a base and a plurality of heat dissipating projections projecting from the base.

3. The device of claim 1 wherein the first electrically conductive connection connects the PCB to a signal input of the IC, and the second electrically conductive connection connects the heat sink to a power input of the IC.

4. The device of claim 3 wherein the second electrically conductive connection is not connected to a signal input of the IC.

5. The device of claim 1 wherein the heat sink is connected to a ground plane.

6. The device of claim 1 wherein the heat sink acts as an EMI (electromagnetic interference) shield for the IC.

7. The device of claim 1 wherein the first electrically conductive connection is a first ball grid array (BGA) and the second electrically conductive connection is a second ball grid array (BGA) and the first BGA has more connecting points than the second BGA.

8. The device of claim 1 wherein the heat sink includes a first electrically conductive layer connected to a ground of the PCB and a second electrically conductive layer connected to a power input of the IC; said first and second electrically conductive layers being electrically insulated from each other.

9. The device of claim 8 wherein the second electrically conductive layer includes a plurality of power rails.

10. A heat sink suitable for mounting on a printed circuit board and dissipating heat from an integrated chip, the heat sink including a base and a plurality of heat dissipating projections projecting from the base, the base including a first electrically conductive layer for connection to ground and a second electrically conductive layer for connection to a power line, the first conductive layer and second electrically conductive layer being electrically insulated from each other by a thermally conductive material.

11. The heat sink of claim 10 wherein the thermally conductive material is a glue, paste or grease with electrically insulating properties.

12. A device comprising an integrated chip (IC), a printed circuit board (PCB) and a heat sink; a first side of the IC faces the PCB and a second side of the IC which is opposite the first side, faces the heat sink; the heat sink comprising a first electrically conductive layer which is connected to a ground plane of the PCB and a second electrically conductive layer which is connected to a power input of the IC; said first conductive layer being electrically insulated from said second electrically conductive layer.

13. The device of claim 12 wherein the first electrically conductive layer is electrically insulated from said second electrically conductive layer by an electrically insulating material which is thermally conductive.

14. The device of claim 12 wherein the IC is connected to the PCB by a first ball grid array (BGA) and connected to the heat sink by a second BGA.

15. The device of claim 14 wherein the IC comprises an IC die and an IC substrate; a first side of the IC substrate being electrically connected to the PCB by the first BGA and a second side of the IC substrate being electrically connected to the heat sink by the second BGA.

16. The device of claim 12 wherein the heat sink is to dissipate heat in a direction away from the IC and PCB.

17. The device of claim 12 wherein the heat sink includes a base and a plurality of heat dissipating members projecting from the base.

18. The device of claim 12 wherein the PCB comprises a signal line and a power line embedded in an insulating material, the power line being electrically connected to the second electrically conductive layer of the heat sink.

19. The device of claim 12 wherein the second electrically conductive layer of the heat sink includes a plurality of separate power lines which are electrically insulated from each other.

20. The device of claim 12 wherein a first power line of said second conductive layer connects to a first power input of the IC and a second power line of said second electrically conductive layer connects to a second power input of the IC, said first and second power inputs having different specified input voltages.
